(19) United States
(12) Patent Application Publication
(10) Pub. No.: US 2006/0284164 A1
(43) Pub. Date: Dec. 21, 2006

(54) Strained germanium field effect transistor and method of making the same

(76) Inventors: Min-Hung Lee, Hsinchu (TW); Cheng-Yeh Yu, Hsinchu (TW); Chee-Wee Liu, Hsinchu (TW)

Correspondence Address: HARNESS, DICKEY & PIERCE, P.L.C., P.O. BOX 8910, RESTON, VA, 20195, US

(21) Appl. No.: 11/216,179

(22) Filed: Sep. 1, 2005

(30) Foreign Application Priority Data
Jun. 15, 2005 (TW) 94119896

(51) Int. Cl. H01L 31/00

(52) U.S. Cl. 257/19

(57) ABSTRACT

A strained germanium field effect transistor (FET) and method of making the same, comprise forming a germanium layer on a substrate, then forming a Si protective layer on the germanium layer, next forming a gate insulation layer on the Si protective layer, and fmally positioning a gate on the gate insulation layer. The germanium layer is used as a carrier transport channel of the strained germanium FET to improve the drive current and the carrier mobility, and to increase the devices performance effectively. And because the Si protective layer is on the germanium layer, the interface property between the germanium layer and the gate insulation layer is improved.

### BACKGROUND

1. Field of Invention

The present invention relates to a field effect transistor (FET), and particularly to a strained germanium FET and method of making the same.

2. Related Art

For a long time, Germanium (Ge) is considered to have better carrier mobility than Si, and the strained Ge also exhibits more excellent transport property than Si or strained Si, therefore, the application of the Ge process is considered to be one of the candidate of developing the high performance property of the Complementary Metal Oxide Semiconductor (CMOS) in the future. However, nowadays, the Ge process technique is difficult to fabricate a strained Ge with high quality. The earth content of Ge is far rarer than Si. The process cost is very high. And it has not been found that the Ge has the similar perfect interface as that between Si and SiO₂. These are all the difficulties in substituting the Si with the Ge in the transistor processes well as the main process of the CMOS.

The Ge channel transistor structure according to the prior art (U.S. Pat. No. 6,723,622) is the epitaxial pure Ge growing on a relaxed SiGe layer. In order to reduce the defects caused by the lattice mismatch of the relaxed SiGe layer and the Si substrate, a thick SiGe graded buffer layer (about 10 μm) is grown between the Si substrate and the relaxed SiGe layer. However, the recent growing method of it is difficult to obtain the higher Ge concentration and the relaxed SiGe buffer with high quality. This may lead threading dislocation defects to the relaxed SiGe buffer layer. Due to lattice constant mismatch results a crosshatch on the SiGe surface, such that the surface is rough and the transistor quality is degraded.

Another prior art (U.S. Pat. No. 6,287,903) is to cover the Si crystal substrate with an epitaxial ultrathin Ge layer (about 1.5 nm) as a protective layer to add an interfacial layer between the Si crystal substrate and a high-K dielectric layer, the carrier channel of which is still the Si crystal material.

### SUMMARY

The present invention provides a strained Ge FET and method of making the same, in which a Ge layer is used as a carrier channel of a strained Ge FET, to improve the drive current and the carrier mobility, and thereby to solve the problems existed in the prior arts.

A strained Ge FET disclosed in the present invention mainly comprises a substrate, a Ge layer, a Si film protective layer, a gate insulation layer and a gate. The Ge layer is formed on the substrate. The Si film protective layer is formed on the Ge layer. The gate insulation layer is located on the Si film protective layer. And the gate is located on the gate insulation layer. This strained Ge FET uses the Ge layer which is a strained Ge layer as a carrier transport channel of the FET, to improve the drive current and carrier mobility, and to increase the devices performance effectively, wherein the strained Ge layer and the Si film protective layer are formed with a low-temperature epitaxy method, while the strained Ge layer can be a pure Ge layer or a SiGe alloy layer. In order to improve the grow effect of the strained Ge layer, a Si buffer layer can be grown previously before growing the strained Ge layer, to assist the formation of the strained Ge layer. And since the Si film protective layer is on the strained Ge layer, the interface property of the strained Ge layer and the gate insulation layer is improved.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only for, and thus are not limitative of the present invention, and wherein:

FIG. 1A is a schematic view of a strained Ge layer grown directly on a Si crystal substrate;

FIG. 1B is a schematic view of a strained Ge FET fabricated directly on a Si crystal substrate;

FIG. 2A is a schematic view of a strained Ge layer grown directly on a Si buffer layer;

FIG. 2B is a schematic view of a strained Ge FET fabricated directly on a Si buffer layer;

FIG. 3 is a simulation view of an inversion layer thickness of a transistor operated under the inversion region, which is calculated by the simulation software;

FIG. 4 is a Raman shift spectrum for the bulk Ge FET and strained Ge FET;

FIG. 5 is a plot of the interface trap density of bulk Si FET and strained Ge FET (strained Ge FETs have different Si protective thickness);

FIG. 6 is a graph of the drain current output characteristics of bulk Si FET and strained Ge FET; and

FIG. 7 is a comparison of hole mobility for bulk Si FET and strained Ge FET.

### DETAILED DESCRIPTION

The present invention will be described in details with the embodiments in order to further illustrate the objects, constructions, features and functions of the present invention. The descriptions about the summary mentioned above and the detailed description below are used to illustrate and explain the principles of the present invention, and to provide a further explanation of the claims of the present invention.

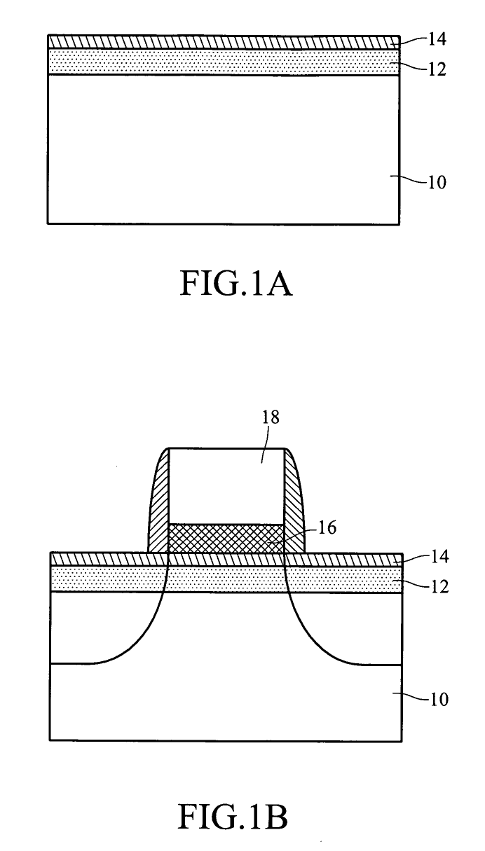

Referring to FIG. 1A, it is a schematic view of a strained Ge layer grown directly on a Si crystal substrate. A FET substrate can be obtained by growing a Ge layer 12 on a Si crystal substrate 10, then growing a Si film protective layer 14 on the Ge layer 12, wherein the orientation of the Si crystal substrate 10 is shown as (100), (110) or (111), and the Si crystal substrate 10 can also be a Si on insulator (SOI) substrate, while the Ge layer 12 can be a pure Ge layer or a SiGe alloy layer. Referring to FIG. 1B, it is a schematic view of a strained Ge FET grown directly on a Si crystal substrate, wherein the Ge layer 12 is fabricated with a low-temperature epitaxy technique, with a thickness ranging from 1 nm to 100 nm. The Ge layer 12 in the present embodiment is formed by compressively strain the epitaxy at 525° C. using the Ultra High Vacuum Chemical Vapor Deposition (UHVCVD), with a thickness about 4 nm, as a transistor carrier channel. While the Si film protective layer 14 is used as an interface of the gate insulation layer 16 for protecting the Ge layer 12 and the transistor, with a thickness ranging from 0.5 nm to 20 nm. The Si film protective layer 14 of the present embodiment is formed at 525° C. by the UHVCVD, with a thickness about 3 nm. Since a Si film protective layer 14 is on the surface of the substrate, the gate insulation layer 16 of the transistor can be SiO₂ or high-K dielectric layer material, to obtain a better interface equivalent to the conventional Si process transistor.

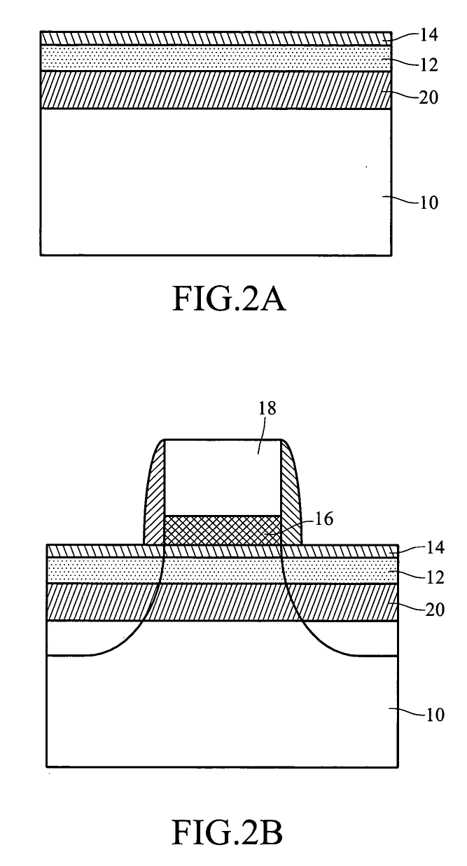

FIG. 2A is a schematic view of a strained Ge FET substrate grown directly on a Si buffer layer, wherein another strained Ge FET substrate can be obtained by mainly forming a Si buffer layer 20 on a Si crystal substrate 10, next forming a Ge layer 12 on the Si buffer layer 20, and finally forming a Si film protective layer 14 on the Ge layer 12, wherein the thickness of the Si buffer layer is ranging from 0˜1000 μm. Referring to FIG. 2B, it is a strained Ge FET grown directly on a Si buffer layer, wherein the Si buffer layer 20 is formed by the epitaxial Si growth at 525° C. by using the UHVCVD, with a thickness about 40 nm, for assisting the growth of the Ge layer 12.

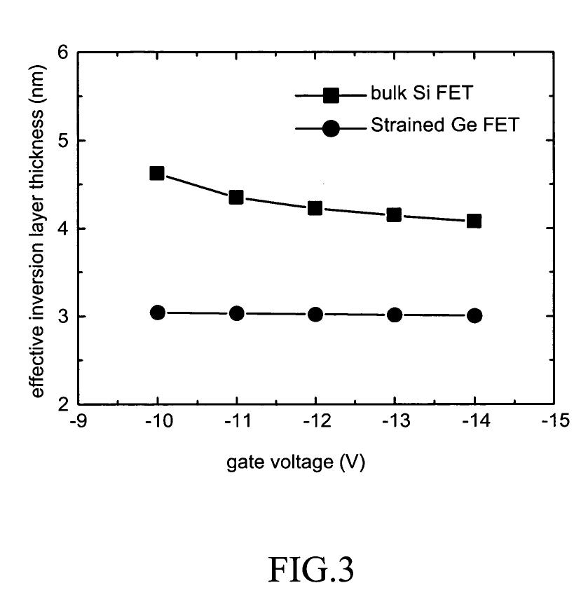

FIG. 3 is a simulation view of an inversion layer thickness of a transistor operated under the inversion region, which is calculated by the simulation software. It can be seen from the simulation view that the inversion layer thickness of the strained Ge FET is thinner than that of the Si FET, due to the quantum confinement effect, and the inversion layer thickness of the strained Ge FET is about 3 nm. In order to enable the carriers transport in the Ge layer 12 to utilize the excellent transport characteristics of the strained Ge, the Ge layer 12 of the present embodiment should thicker than 3 nm.

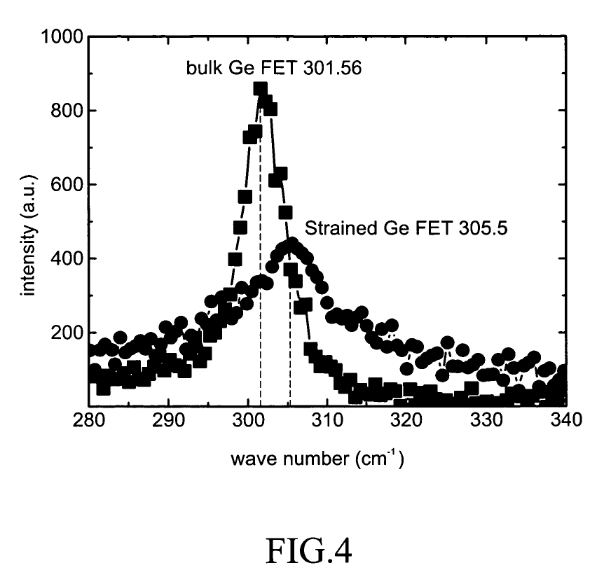

FIG. 4 is a Raman shift spectrum for the bulk Ge substrate and strained Ge layer. According to the Raman shift data of the strained Ge layer compared with the bulk Ge substrate, it can confirm that the Ge layer 12 of the strained Ge substrate is indeed under compressively strain.

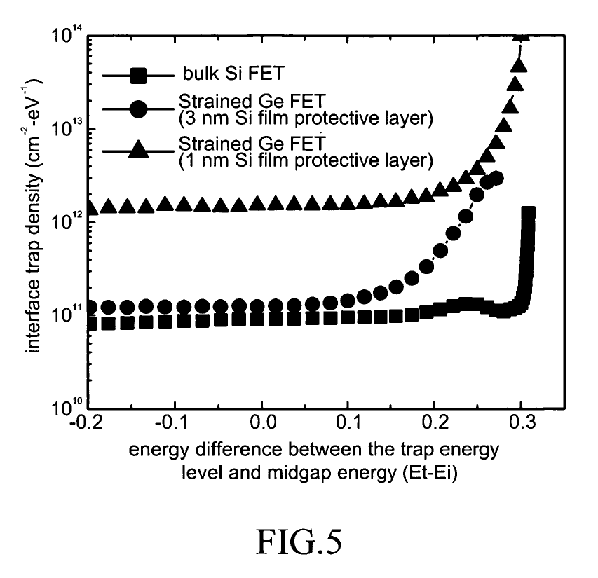

FIG. 5 is a plot of the interface trap density of bulk Si FET and strained Ge FET. It can be observed from the comparison of the interface trap density, since the Si film protective layer 14 is on the Ge layer 12, if the Si protective layer 14 is thicker than 3 nm, the interface trap density on the surface of the strained Ge FET is similar to that of the bulk Si FET, and thereby the disadvantages of the Ge channel transistor high interface trap density with 1 nm Si protective layer are prevent effectively.

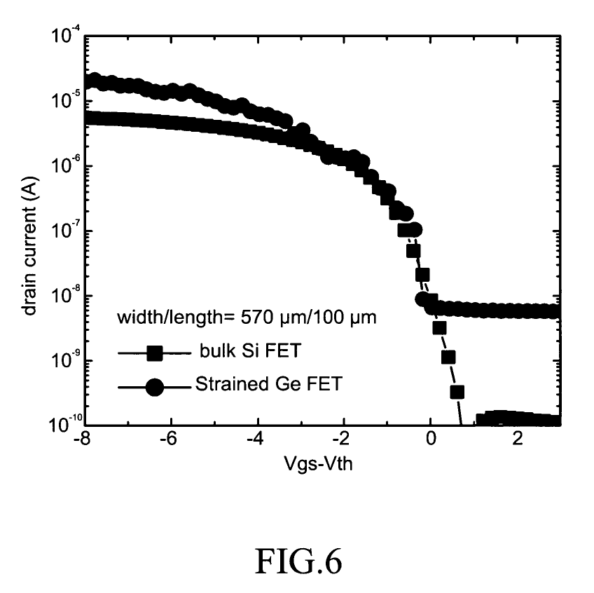

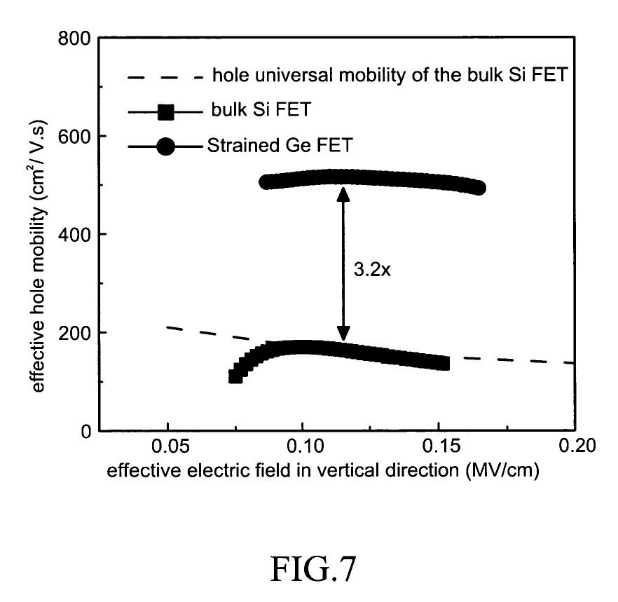

FIG. 6 is a graph of the drain current output characteristics of bulk Si FET and strained Ge FET. It can be observed that the strained Ge FET can improve the drain output current effectively. FIG. 7 is a comparison of hole mobility for bulk Si FET and strained Ge FET. It can be observed from that the strained Ge FET can improve the hole mobility by approximately 3.2 times effectively.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A strained Ge FET, comprising:
a substrate;
a Ge layer on the substrate;
a Si protective layer on the Ge layer;
a gate insulation layer located on the Si protective layer; and
a gate located on the gate insulation layer.

2. The strained Ge FET of claim 1, wherein the substrate is a Si crystal substrate or a Si on insulator (SOI) substrate.

3. The strained Ge FET of claim 2, wherein the grow orientation of the Si crystal substrate is shown as (100), (110) or (111).

4. The strained Ge FET of claim 1, wherein the thickness of the Ge layer is ranging from 1 nm to 100 nm.

5. The strained Ge FET of claim 1, wherein the Ge layer is a pure Ge layer or a SiGe alloy layer.

6. The strained Ge FET of claim 1, further comprising a Si buffer layer formed between the substrate and the Ge layer.

7. The strained Ge FET of claim 6, wherein the thickness of the Si buffer layer is ranging from 0˜1000 μm.

8. The strained Ge FET of claim 1, wherein the thickness of the Si film protective layer is ranging from 0.5 nm to 20 nm.

9. The strained Ge FET of claim 1, wherein the Ge layer and the Si film protective layer are formed by a low-temperature epitaxy method under a temperature ranging from 200° C. to 700° C.

10. The strained Ge FET of claim 9, wherein the low-temperature epitaxy method is a Chemical Vapor Deposition (CVD) method or a Molecular Beam Epitaxy (MBE) method.

11. The strained Ge FET of claim 1, wherein the gate insulation layer is a SiO₂ material or a high-K dielectric layer material.

12. A fabrication method of a strained Ge FET, comprising the steps of:
providing a substrate;
forming a Ge layer on the substrate;
forming a Si protective layer on the Ge layer;
forming a gate insulation layer on the Si film protective layer; and
forming a gate on the gate insulation layer.

13. The fabrication method of the strained Ge FET of claim 12, wherein the substrate is a Si crystal substrate or a SOI substrate.

14. The fabrication method of the strained Ge FET of claim 13, wherein the orientation of the Si crystal substrate is shown as (100), (110) or (111).

15. The fabrication method of the strained Ge FET of claim 12, wherein the thickness of the Ge layer is ranging from 1 nm to 100 nm.

16. The fabrication method of the strained Ge FET of claim 12, wherein the Ge layer is a pure Ge layer or a SiGe alloy layer.

17. The fabrication method of the strained Ge FET of claim 12, wherein the thickness of the Si film protective layer is ranging from 0.5 nm to 20 nm.

18. The fabrication method of the strained Ge FET of claim 12, wherein between the step of providing a substrate and the step of forming a Ge layer on the substrate further comprising:
forming a Si buffer layer between the substrate and the Ge layer.

19. The fabrication method of the strained Ge FET of claim 18, wherein the thickness of the Si buffer layer is ranging from 0˜1000 μm.

20. The fabrication method of the strained Ge FET of claim 12, wherein the Ge layer and the Si film protective layer are formed with a low-temperature epitaxy method under a temperature ranging from 200° C. to 700° C.

21. The fabrication method of the strained Ge FET of claim 20, wherein the low-temperature epitaxy method is a CVD method or a MBE method.

22. The fabrication method of the strained Ge FET of claim 12, wherein the gate insulation layer is a SiO₂ material or a high-K dielectric layer material.
